(19) United States
(12) Patent Application Publication
(10) Pub. No.: US 2014/0000793 A1
(43) Pub. Date: Jan. 2, 2014

(54) METHOD OF MANUFACTURING AN LED

(71) Applicant: NITTO DENKO CORPORATION, Osaka (JP)

(72) Inventors: Tomokazu TAKAHASHI, Ibaraki-shi (JP); Shinya AKIZUKI, Ibaraki-shi (JP); Toshimasa SUGIMURA, Ibaraki-shi (JP); Takeshi MATSUMURA, Ibaraki-shi (JP); Daisuke UENDA, Ibaraki-shi (JP)

(21) Appl. No.: 13/913,807

(22) Filed: Jun. 10, 2013

(30) Foreign Application Priority Data
Jun. 28, 2012 (JP) 2012-145449

(51) Int. Cl. H01L 33/00

(52) U.S. Cl. CPC H01L 33/005
USPC 156/154

(57) ABSTRACT

A method of manufacturing an LED according to an embodiment of the present invention includes back-grinding a substrate of an LED wafer including a light emitting element and the substrate, where the back-grinding includes fixing the LED wafer to a table via a double-sided pressure-sensitive adhesive sheet, and then grinding the substrate.

This application claims priority under 35 U.S.C. Section 119 to Japanese Patent Application No. 2012-145449 filed on Jun. 28, 2012, which are herein incorporated by references.

### BACKGROUND OF THE INVENTION

1. Field of the Invention

The present invention relates to a method of manufacturing an LED.

2. Description of the Related Art

Hitherto, in manufacture of an LED, a light emitting element is laminated on a substrate to form an LED wafer, and then a surface of the substrate on a side opposite to the light emitting element is ground (back-ground) to thin the substrate (for example, Japanese Patent Application Laid-open Nos. 2005-150675 and 2002-319708). Generally, this grinding is carried out while fixing a surface of the substrate on the light emitting element side to a table via a pressure-sensitive adhesive wax. The LED wafer that has undergone grinding is subjected to, for example, steps of heating the wax to release the LED wafer, cleaning the wax adhering on the LED wafer, cutting (dicing) the LED wafer to singulate small element pieces, and forming a reflective layer on the surface of the substrate on the side opposite to the light emitting element.

The above-mentioned back-grinding step is a step of grinding the LED wafer to be very thin. Therefore, during the grinding, there is a problem in that damage such as cracking easily occurs in the LED wafer. In addition, there are such problems that man-hours are required to apply and clean the wax, and that the environmental load is large because a solvent is used to clean the wax. Moreover, there is a problem in that the LED is negatively affected by cleaning liquid.

### SUMMARY OF THE INVENTION

The present invention has been made to solve the above-mentioned conventional problem, and has an object to provide a method of manufacturing an LED with a small environmental load, which is simple and capable of manufacturing an LED with high yields by preventing damage to the LED wafer.

A method of manufacturing an LED according to an embodiment of the present invention includes back-grinding a substrate of an LED wafer including a light emitting element and the substrate,
wherein the back-grinding includes fixing the LED wafer to a table via a double-sided pressure-sensitive adhesive sheet, and then grinding the substrate.

In an embodiment of the present invention, the double-sided pressure-sensitive adhesive sheet includes, on at least one surface thereof, a heat-releasable pressure-sensitive adhesive layer.

In an embodiment of the present invention, the double-sided pressure-sensitive adhesive sheet includes a base member and a heat-releasable pressure-sensitive adhesive layer formed on one surface of the base member, and the LED wafer is fixed to the table under a state in which the heat-releasable pressure-sensitive adhesive layer is attached to the LED wafer.

In an embodiment of the present invention, the double-sided pressure-sensitive adhesive sheet includes a base member and a heat-releasable pressure-sensitive adhesive layer formed on one surface of the base member, and the LED wafer is fixed to the table under a state in which the heat-releasable pressure-sensitive adhesive layer is attached to the table.

In an embodiment of the present invention, the double-sided pressure-sensitive adhesive sheet includes a base member and heat-releasable pressure-sensitive adhesive layers formed on both surfaces of the base member.

In an embodiment of the present invention, the LED wafer is fixed to the table under a state in which another pressure-sensitive adhesive sheet is further arranged between the double-sided pressure-sensitive adhesive sheet and the LED wafer.

According to the present invention, in the back-grinding step, after the LED wafer is fixed to the table via the double-sided pressure-sensitive adhesive sheet, the LED wafer is ground. In this manner, the LED wafer may be prevented from being damaged to manufacture the LED with high yields. Further, according to the present invention, wax is unnecessary to fix the LED wafer, and hence application and cleaning of the wax are unnecessary. Therefore, the LED may be simply manufactured. Further, the use of cleaning liquid such as a solvent may be avoided, and hence the LED may be simply manufactured with a small environmental load. Further, an adverse effect to the LED due to the cleaning liquid may be prevented.

### BRIEF DESCRIPTION OF THE DRAWINGS

In the accompanying drawings:

FIGS. 1A to 1D are schematic views illustrating a back-grinding step in a method of manufacturing an LED according to an embodiment of the present invention;

FIG. 2 is a schematic sectional view of an LED wafer used in the method of manufacturing an LED according to the embodiment of the present invention;

FIGS. 3A to 3C are schematic views illustrating a back-grinding step in a method of manufacturing an LED according to another embodiment of the present invention;

FIGS. 4A to 4C are schematic views illustrating a back-grinding step in a method of manufacturing an LED according to still another embodiment of the present invention;

FIGS. 5A to 5C are schematic views illustrating a back-grinding step in a method of manufacturing an LED according to further another embodiment of the present invention;

FIGS. 6A to 6C are schematic views illustrating a back-grinding step in a method of manufacturing an LED according to yet another embodiment of the present invention;

FIGS. 7A to 7E are schematic views illustrating respective steps after a back-grinding step in a method of manufacturing an LED according to yet another embodiment of the present invention; and

FIGS. 8A to BE are schematic views illustrating respective steps after a back-grinding step in a method of manufacturing an LED according to yet another embodiment of the present invention.

### DETAILED DESCRIPTION OF THE PREFERRED EMBODIMENTS

### A. Back-grinding Step

A method of manufacturing an LED of the present invention includes a back-grinding step of grinding a substrate of an LED wafer including a light emitting element and the substrate.

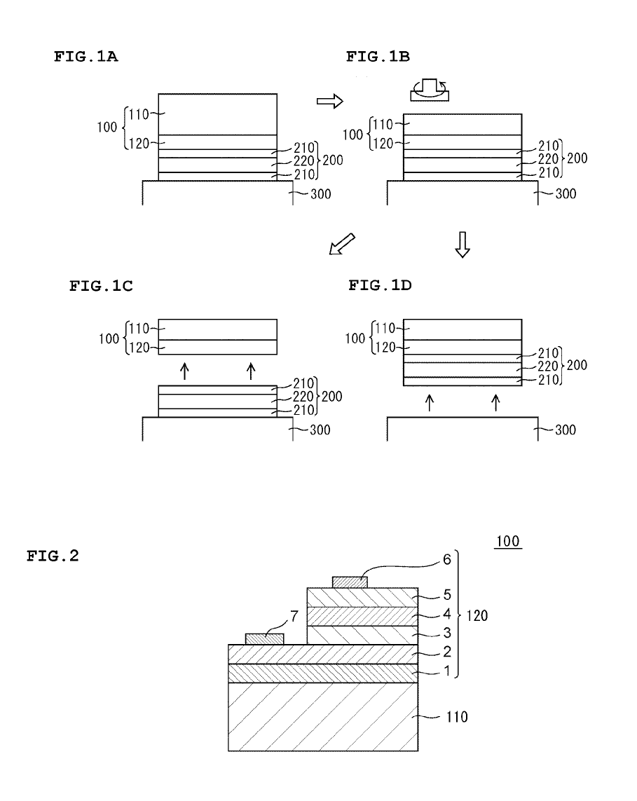

FIGS. 1A to 1D are schematic views illustrating a back-grinding step in a method of manufacturing an LED according to an embodiment of the present invention. Further, FIG. 2 is a schematic sectional view of an LED wafer 100. The LED wafer 100 includes a substrate 110 and a light emitting element 120. The substrate 110 is made of any appropriate material. Examples of the material for constituting the substrate 110 include sapphire, SiC, GaAs, GaN, and GaP. The effect of the present invention, that is, preventing damage to the LED wafer 100, is markedly obtained when the employed LED wafer 100 is made of such a hard and brittle material as those materials. The light emitting element 120 includes a buffer layer 1, an n-type semiconductor layer 2, a light emitting layer 3, a p-type semiconductor layer 4, a transparent electrode 5, and electrodes 6 and 7. The light emitting layer 3 includes, for example, gallium nitride-based compounds (e.g., GaN, AlGaN, and InGaN), gallium phosphide-based compounds (e.g., GaP and GaAsP), gallium arsenide-based compounds (e.g., GaAs, AlGaAs, and AlGaInP), and zinc oxide (ZnO)-based compounds. Note that, although not illustrated, the light emitting element 120 may include any other appropriate members.

In the method of manufacturing an LED of the present invention, first, as illustrated in FIG. 1A, the LED wafer 100 is fixed to a table 300 via a double-sided pressure-sensitive adhesive sheet 200. At this time, the LED wafer 100 is fixed so that the substrate 110 is directed outward (upward). Subsequently, as illustrated in FIG. 1B, the substrate 110 of the LED wafer 100 is ground. With this grinding, the substrate 110 can be thinned to a desired thickness. The thickness of the substrate 110 that has undergone grinding is preferably 10 μm to 500 μm, more preferably 50 μm to 300 μm, most preferably 80 μm to 150 μm. Further, the diameter of the employed LED wafer 100 is preferably 2 inches or more, more preferably 3 inches or more, most preferably 4 inches or more. The upper limit of the diameter of the LED wafer 100 is not particularly limited, but in practical use, the diameter is about 12 inches, for example. In the method of manufacturing an LED of the present invention, the double-sided pressure-sensitive adhesive sheet 200 also has function of protecting the LED wafer 100, and hence the LED wafer 100 may be prevented from being damaged during grinding. Further, the LED wafer 100 can be prevented from being damaged as described above, and hence a large-size (for example, 4 inches or more) LED wafer larger than the conventional one can be handled, and hence the LED can be manufactured with high yields. Subsequently, as illustrated in FIG. 1C or 1D, the LED wafer 100 is released from the table 300. At this time, only the LED wafer 100 may be released from the table 300 while leaving the double-sided pressure-sensitive adhesive sheet 200 on the table 300 (FIG. 1C), or the LED wafer with the double-sided pressure-sensitive adhesive sheet maybe released from the table 300 (FIG. 1D). It is preferred that, as illustrated in FIG. 1D, the LED wafer with the double-sided pressure-sensitive adhesive sheet be released from the table 300. In this manner, the LED wafer 100 may be prevented from being damaged when the LED wafer 100 is released from the table 300.

As the double-sided pressure-sensitive adhesive sheet 200, any appropriate double-sided pressure-sensitive adhesive sheet may be used as long as the effect of the present invention may be obtained. In an embodiment, as illustrated in FIGS. 1A to 1D, the employed double-sided pressure-sensitive adhesive sheet 200 includes a base member 220 and pressure-sensitive adhesive layers 210 formed on both surfaces of the base member 220. As a material for constituting the base member, there may be given, for example: polyolefins such as polyethylene, polypropylene, polybutene, polybutadiene, and polymethylpentene; and polyvinyl chloride, a polyvinyl chloride copolymer, polyethylene terephthalate, polybutylene terephthalate, polyurethane, an ethylene-vinyl acetate copolymer, an ethylene-(meth) acrylic acid copolymer, an ethylene-(meth) acrylate ester copolymer, polystyrene, polycarbonate, polyimide, and a fluorine-based resin. As a form of the base member, there may be given, for example, film, woven fabric, and non-woven fabric. In addition, the base member may be paper or a metal foil. As a material for constituting the pressure-sensitive adhesive layer, there may be given, for example, a rubber-based resin, an acrylic resin, a silicone-based resin, and a polyimide-based resin.

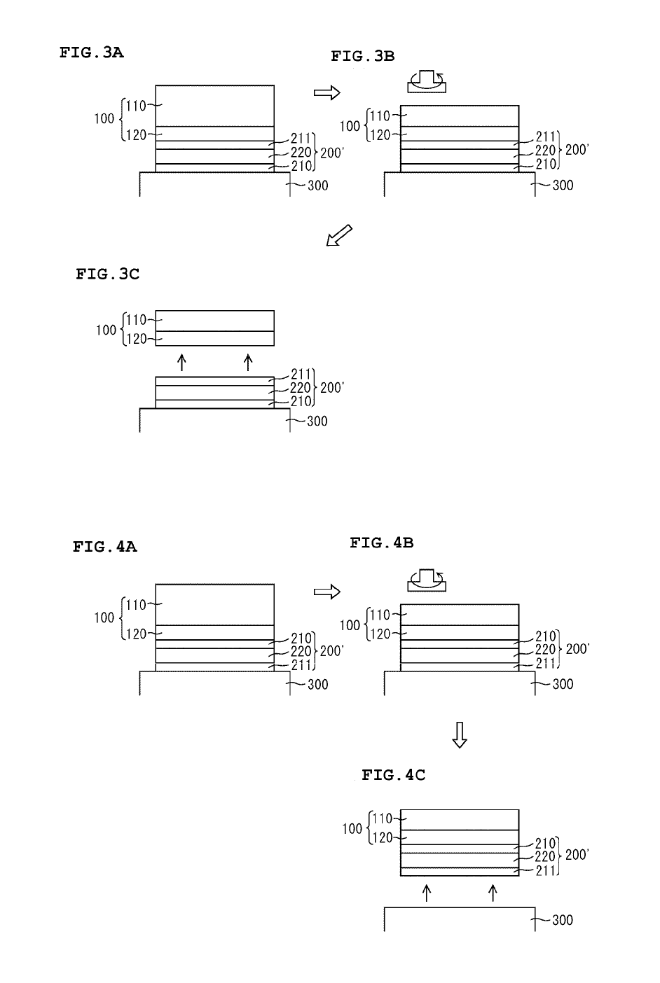

In other embodiments of the present invention, as the double-sided pressure-sensitive adhesive sheet, there is used a double-sided pressure-sensitive adhesive sheet including, on at least one surface thereof, a heat-releasable pressure-sensitive adhesive layer. In this specification, the double-sided pressure-sensitive adhesive sheet including the heat-releasable pressure-sensitive adhesive layer is hereinafter also referred to as “heat-peelable double-sided pressure-sensitive adhesive sheet.” The heat-peelable double-sided pressure-sensitive adhesive sheet can be peeled off when the adhesion of the surface of the heat-releasable pressure-sensitive adhesive layer is reduced or lost by heating. With use of the heat-peelable double-sided pressure-sensitive adhesive sheet, the LED wafer is sufficiently fixed during grinding, and after the grinding, the LED wafer can be easily released. As a result, the LED wafer can be prevented from being damaged more markedly. Further, automated steps can be easily designed. As illustrated in FIGS. 3A to 3C, 4A to 4C, and 5A to 5C, heat-peelable double-sided pressure-sensitive adhesive sheets 200′ and 200″ each include the base member 220 and a heat-releasable pressure-sensitive adhesive layer 211. The heat-releasable pressure-sensitive adhesive layer 211 includes, for example, an adhesive or pressure-sensitive adhesive, and a foaming agent. The heat-peelable double-sided pressure-sensitive adhesive sheet 200′ is peeled off when the foaming agent is foamed or expanded by heating. Any appropriate adhesive (pressure-sensitive adhesive) may be used as the adhesive (pressure-sensitive adhesive), and examples thereof include an acrylic adhesive (pressure-sensitive adhesive), a rubber-based adhesive (pressure-sensitive adhesive), and a styrene-conjugated diene block copolymer-based adhesive (pressure-sensitive adhesive). Any appropriate foaming agent may be used as the foaming agent. Examples of the foaming agent include: inorganic foaming agents such as ammonium carbonate, ammonium hydrogen carbonate, sodium hydrogen carbonate, ammonium nitrite, sodium boron hydride, and an azide; and organic foaming agents such as an alkane chloride fluoride, an azo-based compound, a hydrazine-based compound, a semicarbazide-based compound, a triazole-based compound, and an N-nitroso-based compound. Details of such a heat-peelable double-sided pressure-sensitive adhesive sheet are described in Japanese Patent Application Laid-open Nos. Hei 5-043851, Hei 2-305878, and Sho 63-33487, the contents of which are hereby incorporated by reference into this specification.

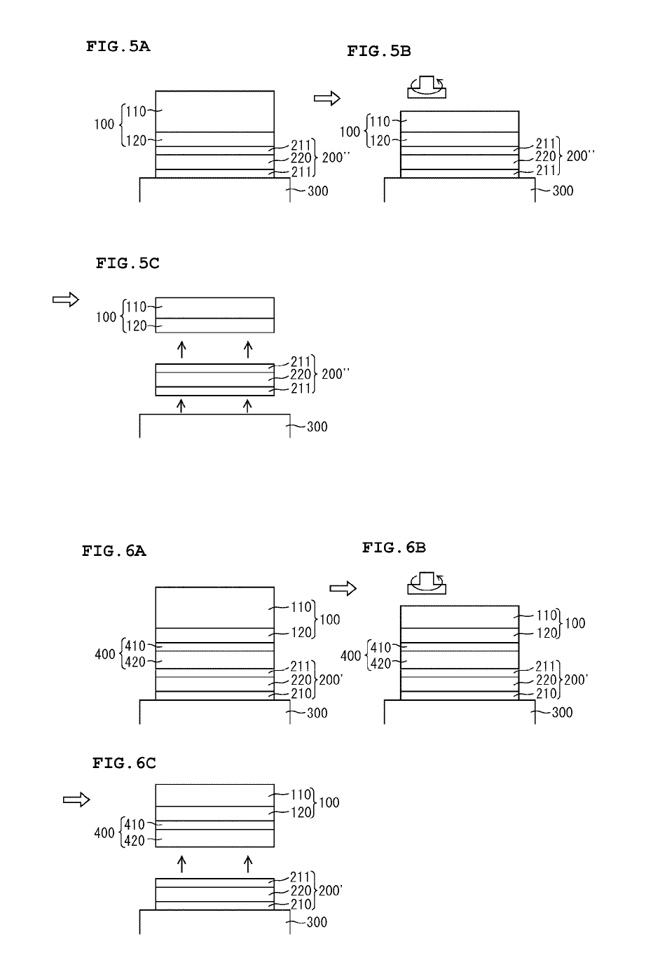

When the heat-peelable double-sided pressure-sensitive adhesive sheet is used as the double-sided pressure-sensitive adhesive sheet, the heat-peelable double-sided pressure-sensitive adhesive sheet may include the heat-releasable pressure-sensitive adhesive layer 211 on one surface of the base member 220 as illustrated in FIGS. 3A to 3C and 4A to 4C, or may include the heat-releasable pressure-sensitive adhesive layers 211 on both surfaces of the base member 220 as illustrated in FIGS. 5A to 5C.

In the embodiment illustrated in FIGS. 3A to 3C, the heat-peelable double-sided pressure-sensitive adhesive sheet 200′ includes the heat-releasable pressure-sensitive adhesive layer 211 on one surface of the base member 220, and the LED wafer 100 is fixed to the table 300 under a state in which the heat-releasable pressure-sensitive adhesive layer 211 is attached to the LED wafer 100 (substantially, to the light emitting element 120). On a surface of the heat-peelable double-sided pressure-sensitive adhesive sheet 200′ on a side opposite to the heat-releasable pressure-sensitive adhesive layer 211 (that is, a surface on the table 300 side), the pressure-sensitive adhesive layer 210 may be provided, and the pressure-sensitive adhesive layer 210 side is attached to the table 300 (FIG. 3A). In the embodiment illustrated in FIGS. 3A to 3C, the substrate 110 is ground (FIG. 3B), and after that, heating is performed so that the LED wafer 100 is released from the heat-peelable double-sided pressure-sensitive adhesive sheet 200′ with the surface of the heat-releasable pressure-sensitive adhesive layer as an origin (FIG. 3C). According to this embodiment, the LED wafer 100 can be prevented from being damaged during grinding. Further, with one operation (heating), the LED wafer 100 can be released.

In the embodiment illustrated in FIGS. 4A to 4C, the heat-peelable double-sided pressure-sensitive adhesive sheet 200′ includes the heat-releasable pressure-sensitive adhesive layer 211 on one surface of the base member 220, and the LED wafer 100 is fixed to the table 300 under a state in which the heat-releasable pressure-sensitive adhesive layer 211 is attached to the table 300. On a surface of the heat-peelable double-sided pressure-sensitive adhesive sheet 200′ on a side opposite to the heat-releasable pressure-sensitive adhesive layer 211 (that is, a surface on the LED wafer 100 side), the pressure-sensitive adhesive layer 210 may be provided, and the pressure-sensitive adhesive layer 210 side is attached to the LED wafer 100 (FIG. 4A). In the embodiment illustrated in FIGS. 4A to 4C, the substrate 110 is ground (FIG. 4B), and after that, heating is performed so that a laminate including the LED wafer 100 and the heat-peelable double-sided pressure-sensitive adhesive sheet 200′ is released from the table 300 with the surface of the heat-releasable pressure-sensitive adhesive layer as an origin (FIG. 4C). In this embodiment, after that, the heat-peelable double-sided pressure-sensitive adhesive sheet 200′ is peeled off from the LED wafer 100. The heat-peelable double-sided pressure-sensitive adhesive sheet 200′ may be peeled off immediately after the back-grinding step, or may be peeled off after performing a predetermined post-process (for example, a reflective layer forming step). According to this embodiment, the LED wafer 100 can be prevented from being damaged during grinding and during handling thereafter, and in addition, it is possible to prevent adhesive residue on the LED wafer 100 after the heat-peelable double-sided pressure-sensitive adhesive sheet 200′ is peeled off.

In the embodiment illustrated in FIGS. 5A to 5C, the heat-peelable double-sided pressure-sensitive adhesive sheet 200″ includes the heat-releasable pressure-sensitive adhesive layer 211 on both surfaces of the base member 220 (FIG. 5A). In the embodiment illustrated in FIGS. 5A to 5C, the substrate 110 is ground (FIG. 5B), and after that, heating is performed so that the LED wafer 100 is released and the heat-peelable double-sided pressure-sensitive adhesive sheet 200″ is peeled off, respectively, with the surface of the heat-releasable pressure-sensitive adhesive layer as an origin (FIG. 5C). According to this embodiment, the LED wafer 100 can be prevented from being damaged during grinding. Further, with one operation (heating), the LED wafer 100 can be released. Further, at the same time when the LED wafer 100 is released, the heat-peelable double-sided pressure-sensitive adhesive sheet 200″ can be peeled off from the table 300. According to this embodiment, a plurality of LED wafers can be continuously and efficiently processed when the plurality of LED wafers are sequentially subjected to the back-grinding step.

Further, according to yet another embodiment of the present invention, as illustrated in FIG. 6A, the LED wafer 100 is fixed to the table 300 under a state in which another pressure-sensitive adhesive sheet 400 is further arranged between the heat-peelable double-sided pressure-sensitive adhesive sheet 200′ and the LED wafer 100. Specifically, the another pressure-sensitive adhesive sheet 400 may be arranged between the heat-releasable pressure-sensitive adhesive layer 211 of the heat-peelable double-sided pressure-sensitive adhesive sheet 200′ and the light emitting element 120 of the LED wafer 100. In this embodiment, the substrate 110 is ground (FIG. 6B), and after that, heating is performed so that a laminate including the LED wafer 100 and the another pressure-sensitive adhesive sheet 400 is released from the heat-peelable double-sided pressure-sensitive adhesive sheet 200′ with the surface of the heat-releasable pressure-sensitive adhesive layer as an origin (FIG. 6C). In this embodiment, after that, the another pressure-sensitive adhesive sheet 400 is peeled off from the LED wafer 100. The another pressure-sensitive adhesive sheet 400 may be peeled off immediately after the back-grinding step, or may be peeled off after performing a predetermined post-process (for example, the reflective layer forming step). According to this embodiment, the LED wafer 100 can be prevented from being damaged during grinding and during handling thereafter, and in addition, it is possible to prevent adhesive residue on the LED wafer 100.

As the another pressure-sensitive adhesive sheet 400, any appropriate pressure-sensitive adhesive sheet may be used. The another pressure-sensitive adhesive sheet 400 includes, for example, a base member 420 and a pressure-sensitive adhesive layer 410 formed on one surface of the base member 420. As the materials for constituting the base member 420 and the pressure-sensitive adhesive layer 410, materials similar to those of the double-sided pressure-sensitive adhesive sheet 200 described above may be used.

Note that, referring to FIGS. 6A to 6C, description has been made of the embodiment in which the heat-peelable double-sided pressure-sensitive adhesive sheet 200′ including the heat-releasable pressure-sensitive adhesive layer 211 on one surface of the base member 220 is used. However, it is needless to say that the heat-peelable double-sided pressure-sensitive adhesive sheet 200″ including the heat-releasable pressure-sensitive adhesive layers 211 on both surfaces of the base member 220 may be used.

As described above, in the method of manufacturing an LED of the present invention, wax is unnecessary, which has been conventionally necessary to fix the LED wafer. Therefore, according to the present invention, application and cleaning of the wax are unnecessary, and the LED can be simply manufactured. Further, the use of cleaning liquid such as a solvent may be avoided, and hence the LED may be simply manufactured with a small environmental load. Further, an adverse effect to the LED due to the cleaning liquid may be prevented.

B. Other Steps (Steps after Back-grinding Step)

The LED wafer 100 that has undergone the back-grinding step, in which the substrate 110 has been ground as described above, is subjected to steps of the post-process including, for example, a step of cutting the LED wafer 100 to singulate small element pieces (dicing step), and a step of forming a reflective layer on the surface of the substrate on the side opposite to the light emitting element (reflective layer forming step).

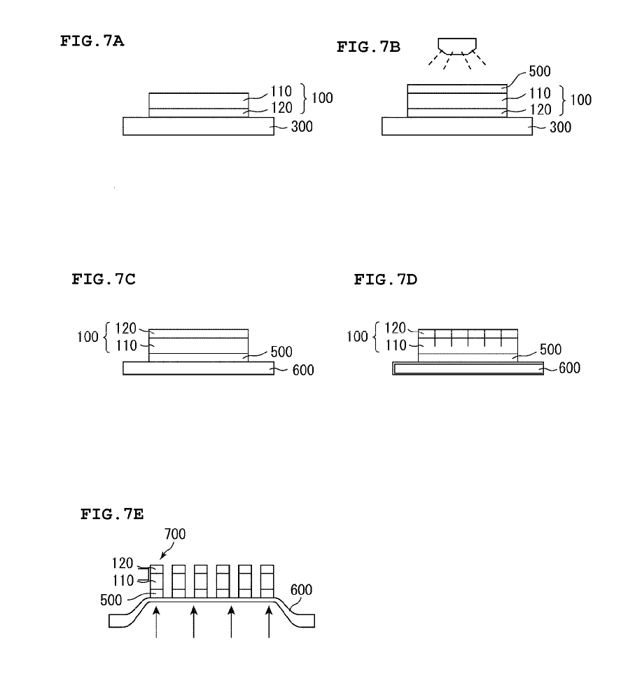

FIGS. 7A to 7E are schematic views illustrating respective steps in a method of manufacturing an LED according to yet another embodiment of the present invention.

In this embodiment, as illustrated in FIGS. 7A and 7B, the LED wafer 100 that has undergone the back-grinding step, is subjected to the reflective layer forming step. Specifically, the LED wafer 100 is placed on the table 300 with the substrate 110 side of the LED wafer 100 up (FIG. 7A). After that, a reflective layer 500 is formed on the outer side of the substrate 110 (FIG. 7B). By forming the reflective layer 500, the amount of light to be extracted from the light emitting element 120 can be increased. As a material for constituting the reflective layer 500, any appropriate material may be used as long as the light from the light emitting element 120 may be satisfactorily reflected. Examples of the material for constituting the reflective layer 500 include metals such as aluminum, silver, gold, palladium, platinum, rhodium, and ruthenium. The reflective layer 500 made of a metal may be formed by, for example, a vapor deposition method (for example, a metal organic chemical vapor deposition method (MOCVD method)). It is preferred that an underlayer made of, for example, SiO₂, TiO₂, ZrO₂, and/or MgF₂ be formed on the outer side of the substrate 110 of the LED wafer 100, and then the reflective layer 500 made of a metal be formed by a vapor deposition method.

After the reflective layer 500 is formed, as illustrated in FIGS. 7C to 7E, the LED wafer 100 having the reflective layer 500 formed thereon is subjected to the dicing step. Specifically, the LED wafer 100 is retained on dicing tape 600 (FIG. 7C). After that, the LED wafer 100 (substantially, the substrate 110) is half-cut in the thickness direction (FIG. 7D). After that, the dicing tape 600 is expanded so that the LED wafer 100 having the reflective layer 500 formed thereon is split from the cut portion as an origin to obtain LEDs 700 singulated into small element pieces (FIG. 7E).

Referring to FIGS. 7D and 7E, description has been made of the embodiment in which the LED wafer 100 is half-cut so as to split the LED wafer 100 from the cut portion as the origin (scribe dicing). As a method of cutting the LED wafer, in addition to the scribe dicing, any appropriate method may be adopted. Examples of other methods include a method of cutting the LED wafer in the entire thickness direction to singulate the small element pieces through expanding, and a method of laser cutting only the center portion of the LED wafer in the thickness direction to split the LED wafer from the cut portion as an origin (stealth dicing).

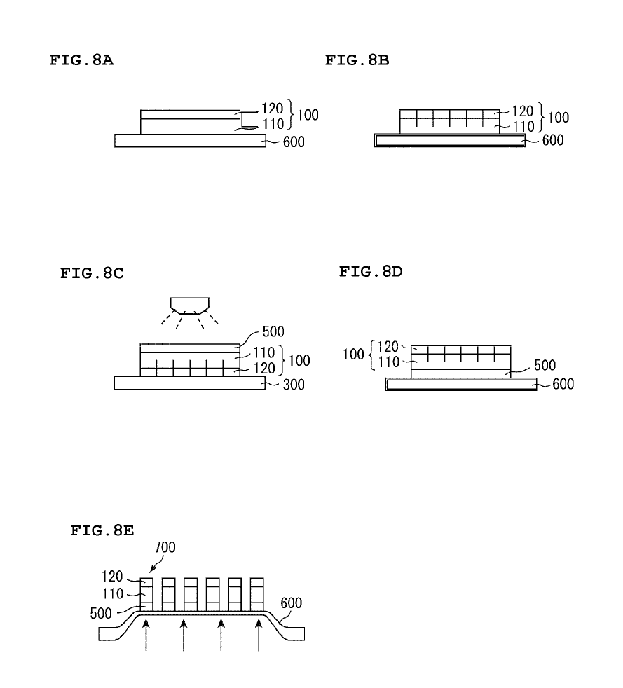

Referring to FIGS. 7A to 7E, description has been made of the embodiment in which, prior to the formation of the cut portion for splitting, the reflective layer forming step is performed. The reflective layer forming step may be performed prior to the formation of the cut portion as described above, or may be performed after the cut portion is formed as illustrated in FIGS. 8A to 8E. In an embodiment of the present invention illustrated in FIGS. &A to 8E, the LED wafer 100 that has undergone the back-grinding step, is retained on the dicing tape 600 (FIG. 8A), and after that, the LED wafer 100 is half-cut (FIG. 8B). Subsequently, the LED wafer 100 having the cut portion formed therein as described above is subjected to the reflective layer forming step. That is, the LED wafer 100 is placed on the table 300 with the light emitting element 120 side down, and the reflective layer 500 is formed on the substrate 110 side of the LED wafer 100 (FIG. 8C). Subsequently, the LED wafer 100 having the reflective layer 500 formed thereon is retained on the dicing tape 600 again with the side on which the cut portion is formed up (FIG. 8D). Thus, the LED wafer 100 is split from the cut portion as an origin, to thereby obtain the LEDs 700 singulated into small element pieces (FIG. 8E).

When the LED wafer that has undergone the back-grinding step includes the double-sided pressure-sensitive adhesive sheet (for example, FIGS. 1D and 4C), in the post-process, the double-sided pressure-sensitive adhesive sheet is peeled off at any appropriate timing. For example, the LED wafer with the double-sided pressure-sensitive adhesive sheet may be retained on dicing tape, and after that, the double-sided pressure-sensitive adhesive sheet may be peeled off. Then, the operations illustrated in FIG. 8A to BE may be performed.

1. A method of manufacturing an LED, the method comprising back-grinding a substrate of an LED wafer including a light emitting element and the substrate,
wherein the back-grinding comprises fixing the LED wafer to a table via a double-sided pressure-sensitive adhesive sheet, and then grinding the substrate.

2. A method of manufacturing an LED according to claim 1, wherein the double-sided pressure-sensitive adhesive sheet comprises, on at least one surface thereof, a heat-releasable pressure-sensitive adhesive layer.

3. A method of manufacturing an LED according to claim 2,
wherein the double-sided pressure-sensitive adhesive sheet comprises a base member and a heat-releasable pressure-sensitive adhesive layer formed on one surface of the base member, and
wherein the LED wafer is fixed to the table under a state in which the heat-releasable pressure-sensitive adhesive layer is attached to the LED wafer.

4. A method of manufacturing an LED according to claim 2,
wherein the double-sided pressure-sensitive adhesive sheet comprises a base member and a heat-releasable pressure-sensitive adhesive layer formed on one surface of the base member, and
wherein the LED wafer is fixed to the table under a state in which the heat-releasable pressure-sensitive adhesive layer is attached to the table.

5. A method of manufacturing an LED according to claim 2, wherein the double-sided pressure-sensitive adhesive sheet comprises a base member and heat-releasable pressure-sensitive adhesive layers formed on both surfaces of the base member.

6. A method of manufacturing an LED according to claim 3, wherein the LED wafer is fixed to the table under a state in which another pressure-sensitive adhesive sheet is further arranged between the double-sided pressure-sensitive adhesive sheet and the LED wafer.
